(19) United States
(12) Patent Application Publication
(10) Pub. No.: US 2011/0086444 A1
(43) Pub. Date: Apr. 14, 2011

(54) PROCESS FOR PRODUCING SUBSTRATES FREE OF PATTERNS USING AN ALPHA STEPPER TO ENSURE RESULTS

(75) Inventors: Wei-Chih Weng, Tainan City (TW); Miau Shing Tsai, Tainan City (TW); Hsun-Ying Huang, Tainan City (TW)

(73) Assignee: TAIWAN SEMICONDUCTOR MANUFACTURING COMPANY, LTD., Hsin-Chu (TW)

(21) Appl. No.: 12/578,707

(22) Filed: Oct. 14, 2009

(51) Int. Cl. H01L 21/66

(52) U.S. Cl. 438/16; 257/E21.53

(57) ABSTRACT

The present disclosure provides a method for making an integrated circuit. The method comprises processing a first surface of a substrate to create the integrated circuit and grinding a second surface of the substrate to remove material until the substrate is substantially close to a desire thickness. The method also includes performing a wet etch process over the second surface of the substrate and performing a chemical mechanical polishing (CMP) process over the second surface of the substrate to remove a pattern on the substrate. The second surface of the substrate is examined with a metrological instrument to determine if the second surface is substantially smooth; if the second surface is not substantially smooth, the steps of performing the CMP process and examining the second surface with the metrological instrument are repeated until the second surface is substantially smooth.

### BACKGROUND

In semiconductor technology, a surface of a substrate can be ground to a thickness sufficient to allow a radiation to pass through to a sensor on the opposite surface of the substrate. This method is used in the fabrication of back-side illuminated imaging devices such as complimentary metal oxide semiconductor (CMOS) image sensors. This grinding can leave spurious patterns in the surface of the substrate, which can distort the radiation as it passes through the substrate surface and lead to imperfections in the image ultimately produced by the image sensor.

It is desired, therefore to have a system and method for fabricating devices such as a back-side illuminated CMOS image sensor where any spurious patterns are removed or reduced from the back-side of the substrate.

Grinding is also a rough-thinning process, which has both benefits and detriments. Grinding is relatively inexpensive by being a less-expensive tool as compared to other tools, such as a chemical mechanical polisher, and is relatively fast. However, grinding is not very accurate when attempting to reach a desired thickness of the substrate.

### SUMMARY

The present disclosure provides an advancement over the prior art, and may, depending on the particular embodiment, be used to achieve one or more of the above-listed desired improvements.

In one embodiment, the present disclosure provides a method for making an integrated circuit. The method comprises providing a substrate having a first surface and a second surface and forming at least one circuit element on the first surface. A rough-thinning process, such as grinding and/or wet etch, is performed on the second surface to remove material until the substrate is substantially close to but exceeds a first thickness, whereby the rough-thinning process leaves a pattern on the second surface. The method further includes performing a chemical mechanical polishing (CMP) process over the substrate to substantially remove the pattern on the second surface and analyzing the substrate after the CMP process to compare the first thickness to a second thickness. If the first thickness is not within a predetermined amount of the second thickness, the CMP process can be repeated.

The present disclosure provides another embodiment of a method for making an integrated circuit device. In this embodiment, the method comprises processing a first surface of a substrate to create the integrated circuit and grinding a second surface of the substrate to remove material until the substrate is substantially close to a desire thickness. The method also includes performing a wet etch process over the second surface of the substrate and performing a chemical mechanical polishing (CMP) process over the second surface of the substrate to remove a pattern on the substrate. The second surface of the substrate is examined with a metrological instrument to determine if the second surface is substantially smooth. If the second surface is not substantially smooth, the steps of performing the CMP process and examining the second surface with the metrological instrument are repeated until the second surface is substantially smooth.

The present disclosure also provides a method for making a back-side illuminated complementary metal oxide semiconductor (CMOS) image sensor. In one embodiment, the method includes, in sequence, providing a substrate with at least one pixel device on a first surface; performing a grinding process on a second surface, opposite the first surface, of the substrate until the substrate is substantially close to a desired thickness; performing a wet etching process over the second surface of the substrate to bring it closer to the desired thickness; and performing a chemical mechanical polishing (CMP) process on the second surface of the substrate. The second surface of the substrate is examined with a profile-detection device to determine if the second surface is substantially smooth after the CMP. If not, the steps of performing the CMP process and examining the substrate are repeated until the substrate is substantially smooth, thereby producing a smooth substrate.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of one embodiment of a method to make a back-side illuminated CMOS image sensor.

FIG. 2 illustrates a sectional side views of an exemplary CMOS image sensor at the first step of the method of FIG. 1.

FIG. 3 illustrates a sectional side views of an exemplary CMOS image sensor after the grinding step of the method of FIG. 1.

FIG. 4 illustrates a sectional side views of an exemplary CMOS image sensor after the wet etching step of the method of FIG. 1.

FIG. 5 illustrates a sectional side views of an exemplary CMOS image sensor after the chemical mechanical polishing (CMP) step of the method of FIG. 1.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

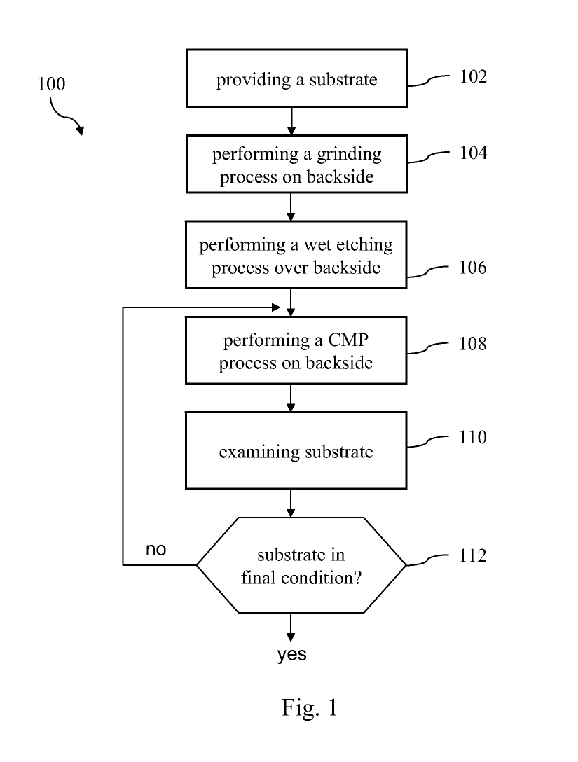

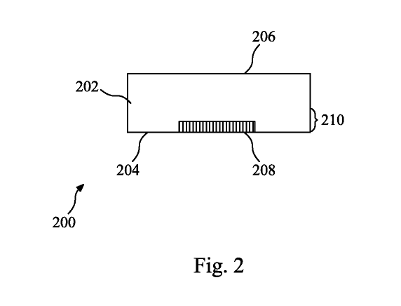

FIG. 1 is a flowchart of one embodiment of a method 100 for making a back-side illuminated CMOS image sensor. FIGS. 2 through 5 illustrate sectional side views of an exemplary sensor 200 during various fabrication stages according to the method 100. With reference to FIGS. 1 through 5, the method 100 and the exemplary image sensor 200 are collectively described below. It is understood that additional steps can be provided before, during, and after the method 100, and some of the steps described below can be replaced or eliminated, for additional embodiments of the method.

The back-side illuminated CMOS image sensor is an example of one device that can benefit from one or more embodiments. Other devices include micro-electro mechanical system (MEMS), deformable mirror devices (DMDs), and other types of image sensors. These different devices may not include some elements discussed below, and may include additional elements not present in a CMOS image sensor.

The method 100 begins at step 102 by providing a substrate 202 shown in FIG. 2. In one embodiment, the substrate 202 comprises silicon. Other devices that can benefit from one or more embodiments may include a different type of substrate, such as Gallium Arsenide (GaAs). The substrate 202 includes at least one pixel device 208 on a first surface 204. The at least one pixel device 208 is operable to detect a radiation that comes in contact with it. In one embodiment, the at least one pixel device 208 is a CMOS image sensor operable to detect visible light. The substrate also includes a second surface 206, referred to as the “backside,” opposite the first surface 204. A desired thickness 210 for the substrate 202 of the finished product of the method 100 is determined based on factors well known in the art.

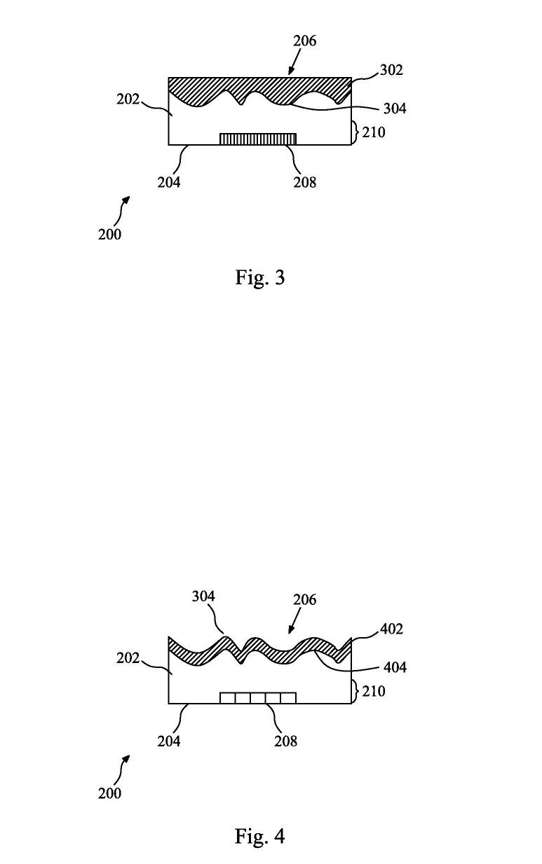

At step 104 of the method 100, the substrate 202 is subjected to a rough-thinning process. Referring to FIG. 3, the rough-thinning process is operable to remove substrate material 302 from the backside 206. The rough-thinning process may include any mechanical or chemical means which removes substrate material 302 in relatively large quantities, leaving behind a pattern 304 in the surface of the substrate. For example, the rough-thinning process may include grinding the backside 206 with a grinding wheel. The rough-thinning process removes substrate material 302 until the thickness of substrate 202 is substantially close to the desired thickness 210. The rough-thinning process of step 104 leaves a pattern 304 in the backside 206 of the substrate 202. This pattern 304 includes regions of differing heights which can distort radiation passing through the substrate 202 through the backside 206

Referring to FIGS. 1 and 4, the method 100 proceeds to step 106 in which an etching process is performed over the backside 206 of the substrate 202. In one embodiment, the etching is performed using an acid, for example, potassium hydroxide (KOH). The wet etching removes substrate material 402 from the surface 304 until the thickness of substrate 202 is closer to the desired thickness 210. After the wet etching step is performed, a pattern 404 remains in the backside 206 of the substrate 202. After step 106, the substrate 202 is close to being thin enough for the radiation to be detected by pixel device 208 to pass through the substrate 202 through backside 206.

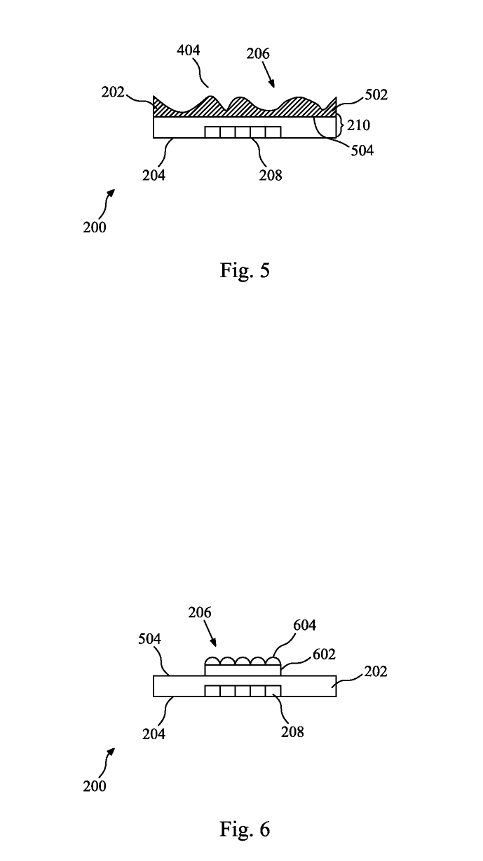

Referring to FIGS. 1 and 5, the method 100 next proceeds to step 108 in which a chemical machine polishing (CMP) process is performed on the backside 206 of the substrate 202. In one example, the CMP process polishes the surface 404 with a chemically reactive slurry, which is a liquid including a suspended abrasive component. The CMP process removes substrate material 502, leaving behind surface profile 504 on surface 206. In some embodiments, a second substrate may be attached to the front surface 204 of the substrate 202 to provide rigidity during the CMP process and to prevent the substrate 202 from breaking. In some embodiments, the CMP process utilized a brush time of 30 seconds, a relatively low brush RPM, and an electro chemical plating flow rate of 150 ml/min. This second substrate is then removed after the CMP process is completed.

The method 100 next proceeds to step 110 in which the substrate is examined. For example, the backside 206 is examined with a profile-detection device. The profile-detection device may be any device operable to examine the surface profile 504 of the backside 206 and determine the differences in height between the high and low regions of the backside 206. In one example, the profile-detection device is an alpha stepper. The profile-detection device produces a quantification of the variances in the surface profile 504. A tolerance value is selected where a variance in surface profile 504 less than the tolerance value indicates that the surface profile 504 is substantially smooth. For example, the tolerance value may be set at 140 angstroms. In addition or in the alternative, a thickness measurement device may be used to determine if the substrate 202 is at (or sufficiently near) the desired thickness 210.

The method 100 next proceeds to step 112, in which the backside 206 and/or the thickness of the substrate 202 is compared with the tolerance value and/or desired thickness. If the substrate is not accepted, execution returns and steps 108 and 110 of the method are repeated. At the positive conclusion of step 112, the surface profile 504 of surface 206 is acceptable, e.g., such that radiation striking surface 206 will pass through undistorted so it can be detected by the at least one pixel device 208.

Referring now to FIG. 6, upon completion of step 112 (FIG. 1), a visible light filter 602 is placed over the surface 504 of the substrate 202 to limit the wavelengths of light that pass through it. In one embodiment, the filter controls the specific wavelengths of light which will hit the at least one pixel device 208. For example, the filter may only permit blue light to pass through. A lens element 604 is placed over the visible light filter 602. The lens element 604 is operable to focus the visible light onto the at least one pixel device 208.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method for making an integrated circuit, comprising:
providing a substrate having a first surface and a second surface;
forming at least one circuit element on the first surface;
performing a thinning process on the second surface to remove material until the substrate is substantially close to but exceeds a first thickness, whereby the thinning process leaves a pattern on the second surface;
performing a chemical mechanical polishing (CMP) process over the substrate to substantially remove the pattern on the second surface;
analyzing the substrate after the CMP process to compare the first thickness to a second thickness; and
if the first thickness is not within a predetermined amount of the second thickness, repeating the CMP process.

2. The method of claim 1, wherein the substrate is composed of silicon.

3. The method of claim 1, wherein the thinning process comprises a mechanical grinding process.

4. The method of claim 3, wherein the thinning process further comprises a wet etching process.

5. The method of claim 1, wherein the substrate after the CMP process has been performed is configured to allow a radiation to pass through.

6. The method of claim 5, further comprising applying a radiation wavelength filter over the second surface of the substrate after the CMP process has been performed.

7. The method of claim 6, wherein the at least one circuit element is a complementary metal oxide semiconductor (CMOS) image sensor configured for detecting the radiation that passes through the filter and the second surface of the substrate.

8. A method for making an integrated circuit device, comprising:
proving a substrate having a first surface and a second surface, wherein an integrated circuit is on the first surface;
grinding the second surface of the substrate until the substrate is substantially close to a desire thickness;
performing a chemical mechanical polishing (CMP) process over the second surface of the substrate;
examining the second surface of the substrate with a metrological instrument to determine if the second surface is substantially smooth;
if the second surface is not substantially smooth, repeating the steps of performing the CMP process and examining the second surface with the metrological instrument until the second surface is substantially smooth.

9. The method of claim 8, wherein the metrological instrument is an alpha stepper .

10. The method of claim 9, wherein a quantification of a variance in surface profile provided by the alpha stepper is used to determine if the substrate is substantially smooth.

11. The method of claim 8, wherein the substrate comprises silicon.

12. The method of claim 8, wherein the substrate after the CMP process has been performed is configured to allow radiation to pass through.

13. The method of claim 12, further comprising applying a radiation filter over the second surface of the substrate to limit the wavelengths of the radiation that reach the first surface.

14. The method of claim 13, further comprising applying a lens over the second surface of the substrate.

15. The method of claim 14, further comprising laying the substrate and the visible light filter over a CMOS image sensor for detecting images in the light that passes through the lens, the filter, and the second surface of the smooth substrate.

16. A method, performed in sequence, for making a back-side illuminated complementary metal oxide semiconductor (CMOS) image sensor, comprising:
providing a substrate with at least one pixel device on a first surface;
performing a grinding process on a second surface, opposite the first surface, of the substrate until the substrate is substantially close to a desired thickness;
performing a wet etching process over the second surface of the substrate to bring it closer to the desired thickness;
performing a chemical mechanical polishing (CMP) process on the second surface of the substrate;
examining the second surface of the substrate with a profile-detection device to determine if the second surface is substantially smooth;
if the substrate is not substantially smooth, repeating the steps of performing the CMP process and examining the substrate until the substrate is substantially smooth.

17. The method of claim 16,
wherein examining the second surface of the substrate is also used to determine if the substrate is at the desired thickness, and
wherein, if the substrate is not at the desired thickness, repeating the steps of performing the CMP process and examining the substrate until the substrate is at the desired thickness.

18. The method of claim 16, wherein a quantification of a variance in surface profile provided by the profile-detection device is used to determine if the substrate is substantially smooth.

19. The method of claim 16, further comprising applying a visible light filter over the second surface of the smooth substrate to limit the wavelengths of light that pass through it.

20. The method of claim 19, further comprising forming a lens element in line with the visible light filter and the at least one pixel device.
